(19) United States
(12) Patent Application Publication
(10) Pub. No.: US 2025/0208404 A1
(43) Pub. Date: Jun. 26, 2025

(54) OPTICAL PULSE STRETCHER APPARATUS

(71) Applicant: Cymer, LLC, San Diego, CA (US)

(72) Inventors: Thao Trieu, San Marcos, CA (US); Gregory Leonard Klotz, La Verne, CA (US)

(21) Appl. No.: 18/850,778

(22) PCT Filed: Mar. 6, 2023
(86) PCT No.: PCT/US2023/014658

§ 371 Date: Sep. 25, 2024

Related U.S. Application Data
(60) Provisional application No. 63/325,972, filed on Mar. 31, 2022.

(51) Int. Cl. G02B 26/00; G02B 27/09; G03F 7/00; G03F 7/20

(52) U.S. Cl. CPC G02B 26/001; G02B 27/09; G03F 7/2004; G03F 7/70008; G03F 7/7055; G03F 7/70825; G03F 7/70883

(57) ABSTRACT

An optical pulse stretcher apparatus includes: a hermetically-sealed container including one or more walls that define an interior cavity that is maintained, in operation, at a controlled environment, at least one wall having one or more windows, each window configured to pass one or more of a pulsed light beam and a stretched pulsed light beam; an optical stretcher arranged within the interior cavity and configured to receive a pulsed light beam and generate at least one stretched pulsed light beam; and one or more actuation devices. Each actuation device physically communicates with an optical element within the interior cavity and includes an adjustment mechanism external to the hermetically-sealed container. The adjustment mechanism enables adjustment of one or more physical properties of the optical element in physical communication with the actuation device without disrupting the controlled environment within the interior cavity.

### CROSS REFERENCE TO RELATED APPLICATIONS

This application claims priority to U.S. Application No. 63/325,972, filed Mar. 31, 2022, titled OPTICAL PULSE STRETCHER APPARATUS, which is incorporated herein in its entirety by reference.

### TECHNICAL FIELD

The disclosed subject matter relates to an optical pulse stretcher apparatus in which optical elements within an interior cavity can be adjusted without disrupting a controlled environment within the interior cavity.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (for example, comprising part of one or several dies) on a substrate (for example, a silicon wafer). Transfer of the pattern is typically by way of imaging onto a layer of radiation-sensitive material (resist) provided on the substrate. In general, a single substrate will contain a network of adjacent target portions that are successively patterned. Known lithographic apparatus includes so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

A light (or laser) source can be used, for example, for generating illumination radiation for illuminating the patterning device with of the lithographic apparatus. The laser source can include a high power gas discharge laser system and an optical pulse stretcher configured to lengthen the pulse of the output of the high power gas discharge laser system.

### SUMMARY

In some general aspects, an optical pulse stretcher apparatus includes: a hermetically-sealed container including one or more walls that define an interior cavity that is maintained, in operation, at a controlled environment, at least one wall having one or more windows, each window configured to pass one or more of a pulsed light beam and a stretched pulsed light beam; an optical stretcher arranged within the interior cavity and configured to receive a pulsed light beam and generate at least one stretched pulsed light beam; and one or more actuation devices. Each actuation device physically communicates with an optical element within the interior cavity and includes an adjustment mechanism external to the hermetically-sealed container. The adjustment mechanism enables adjustment of one or more physical properties of the optical element in physical communication with the actuation device without disrupting the controlled environment within the interior cavity.

Implementations can include one or more of the following features. For example, the adjustment mechanism enabling adjustment of one or more physical properties of the optical element can include the adjustment mechanism enabling one or more of a translation of the optical element along any direction and a rotation of the optical element about any direction. The adjustment mechanism enabling the translation of the optical element along a direction can include enabling translation of the optical element within an adjustment range of ±3 millimeters (mm) and with a nominal position accuracy of less than 300 micrometers (μm), and the adjustment mechanism enabling the rotation of the optical element about a direction can include enabling rotation of the optical element within an adjustment range of ±5 degrees and with a nominal angular accuracy of less than 0.1 deg.

The optical element that is in physical communication with the actuation device can include a mirror, a concave mirror, a beam splitter, or a prism. The optical element that is in physical communication with the actuation device can include an alignment apparatus including a prism and a fluorescent screen arranged in fixed relationship to each other. The optical pulse stretcher apparatus can also include a viewport arranged in a wall of the hermetically-sealed container relative to the fluorescent screen such that the fluorescent screen is visible from outside the hermetically-sealed container through the viewport. The actuation device physically communicating with the alignment apparatus can be configured to translate the alignment apparatus from a first position at which the prism interacts with one or more of the pulsed light beam and the stretched pulsed light beam and a second position at which the prism does not interact with any pulsed light beam or stretched pulsed light bean.

Each actuation device can include a bushing hermetically sealed within a wall of the container and a driving element configured to move relative to the bushing, the driving element physically communicating with the optical element. The bushing can be positioned and fixed within a bore of a wall of the container and the driving element can include the adjustment mechanism at a first end and a shaped-tip driver at a second end, the shaped-tip driver sized to interact with a shaped socket physically communicating with the optical element. The shaped socket can include a conical feed-through feature configured to align the shaped-tip driver with the shaped socket. Rotation of the adjustment mechanism at the first end can translate the shaped-tip driver at the second end, which thereby translates the shaped socket in physical communication with the optical element. The shaped-tip driver can be a hex-tip driver and the shaped socket can be a hex socket. An interior of the bushing can receive the adjustment mechanism and the interface between the bushing and the adjustment mechanism can be a threaded interface such that rotation of the adjustment mechanism causes the adjustment mechanism to also translate relative to the bushing and causes the shaped-tip driver to translate and rotate relative to the bushing. The threaded interface can include rounded-tipped threads at the interior of the bushing that mate with rounded-tipped threads at an exterior of the adjustment mechanism. The bushing and the adjustment mechanism can each be made of non-leaded metals or non-leaded metal alloys and the interface lacks lubricant. The threaded interface can include threads at the interior of the bushing that mate with threads at the exterior of the adjustment mechanism, the threads having a pitch of 80-100 teeth per inch. The shaped-tip driver can be in elastic engagement with the adjustment mechanism. The driving element can remain in physical communication with the optical element during all range of motions within the bushing. The adjustment mechanism can enable adjustment of one or more physical properties of the optical element in physical communication with the actuation device while passing one or more pulsed light beams and stretched pulsed light beams through the window, and while operating the pulsed light beams and stretched pulsed light beam at repetition rates greater than 500 Hertz (Hz), greater than 1000 Hz, or greater than 3000 Hz.

The controlled environment can be gas purged and maintained at a pressure greater than atmospheric pressure, or at a pressure that is about 15-22 pounds per square inch (PSI).

The optical stretcher can include two or more stacked confocal optical pulse stretchers arranged within the interior cavity. A first of the stacked confocal optical pulse stretchers can include a first plurality of mirrors and can be configured to receive a portion of the pulsed light beam and generate a first stretched pulsed light beam by reflecting the portion of the pulsed light beam at the first plurality of mirrors. A second of the stacked confocal optical pulse stretchers can include a second plurality of mirrors and can be configured to receive a portion of the first stretched pulsed light beam and generate a second stretched pulsed light beam by reflecting the portion of the first stretched pulsed light beam at the second plurality of mirrors. The first plurality of mirrors and the second plurality of mirrors can include concave mirrors.

The optical element that is in physical communication with the actuation device can include an optical element of the optical stretcher.

In other general aspects, a deep ultraviolet (DUV) light source includes an optical pulse stretcher apparatus. The optical pulse stretcher apparatus includes: a hermetically-sealed container including one or more walls that define an interior cavity that is maintained, in operation, at a controlled environment, at least one wall having one or more windows, each window configured to pass one or more of a pulsed light beam and a stretched pulsed light beam; an optical stretcher arranged within the interior cavity and configured to receive a pulsed light beam and generate at least one stretched pulsed light beam; and one or more actuation devices. Each actuation device physically communicates with an optical element within the interior cavity and includes an adjustment mechanism external to the hermetically-sealed container. The adjustment mechanism enables adjustment of one or more physical properties of the optical element in physical communication with the actuation device without disrupting the controlled environment within the interior cavity.

### DESCRIPTION OF DRAWINGS

The accompanying drawings, which are incorporated herein and form part of the specification, illustrate the present invention and, together with the description, further serve to explain the principles of the present invention and to enable a person skilled in the relevant art(s) to make and use the present invention. One or more of the drawings may not be to scale.

FIG. 1 is a block diagram of an optical pulse stretcher apparatus including an optical stretcher arranged within an interior cavity of a hermetically-sealed container defined by a plurality of walls and one or more through-wall adjusters or actuation devices configured to enable adjustment of optical elements within the interior cavity;

FIG. 2A is a perspective view of an implementation of an actuation device that is mounted to a wall of the container of FIG. 1, the actuation device including an adjustment mechanism positioned external to the interior cavity, and a driver inside the interior cavity and engaging with a region or portion of an optical element, the driver moveable along an axial direction relative to a bushing fixed within the wall;

FIG. 2B is a side cross-sectional view of the actuation device of FIG. 2A;

FIG. 2C is a side cross-sectional view of the actuation device of FIG. 2A mounted to the wall of the container of FIG. 1;

FIG. 2D is a cross-sectional view of the actuation device of FIG. 2C taken along plane 2D-2D;

FIG. 2E is a cross-sectional view of the actuation device of FIG. 2C taken along plane 2E-2E;

FIG. 3A is a perspective view of an implementation of the bushing within the actuation device of FIGS. 2A-2E;

FIG. 3B is a perspective view of an implementation of a driving element including a body that includes, at a first end, the adjustment mechanism and, at a second end, the driver, the driving element, when mounted within the actuation device, extends axially along a central opening of the bushing;

FIG. 3C is a detail view 3C of an interface between the driving element and the bushing of FIG. 2C;

FIG. 4 is a block diagram of an implementation of the optical pulse stretcher apparatus of FIG. 1 in an implementation of a pulsed light source that is configured to supply a light beam to a photolithography exposure apparatus for generating a circuit pattern on a target portion of a substrate (or wafer);

FIG. 5A is a block diagram of an implementation of an optical pulse stretcher apparatus including a first optical pulse stretcher device and a second optical pulse stretcher device arranged as a series of stacked optical pulse stretcher devices;

FIG. 5B is a block diagram of an implementation of an optical arrangement within the second optical pulse stretcher device, the optical arrangement configured to receive a first stretched pulsed light beam from the first optical pulse stretcher device, to split the first stretched pulsed light beam into portions, to redirect the split portions into one or more of pulse stretchers of the second optical pulse stretcher device, and to recombine the split portions that have been delayed to form a second stretched pulsed light beam directed to the first optical pulse stretcher device;

FIG. 6A is a block diagram of an implementation of an actuation device and associated alignment apparatus are shown in a side cross-sectional view and while the alignment apparatus is out of the path of a light beam;

FIG. 6B is a block diagram of the implementation of the actuation device and the associated alignment apparatus of FIG. 6A shown in a side cross-sectional view and while the alignment apparatus is in the path of the light beam;

FIG. 6C is a plan view looking toward a wall of the container that houses the alignment apparatus while the alignment apparatus is out of the path of the light beam as in FIG. 6A;

FIG. 6D is a plan view looking toward the wall of the container that houses the alignment apparatus while the alignment apparatus is in the path of the light beam as in FIG. 6B;

FIG. 7 is a perspective view of an implementation of an optical element that is adjusted with three actuation devices at three distinct points on a back surface of the optical element;

FIGS. 8A-8C show side cross-sectional views through the mirror, one of a set of adapters, and one of respective actuation devices of FIG. 7; with FIG. 8A showing neutral position of the adjustment mechanism of the actuation device, FIG. 8B showing a position at which the adjustment mechanism has been turned (for example, clockwise when facing the wall outside the interior cavity) relative to the position shown in FIG. 8A, and FIG. 8C showing a position at which the adjustment mechanism has been turned (for example, counter-clockwise when facing the wall from outside the interior cavity relative to the position shown in FIG. 8A; and

FIG. 8D shows a cross-sectional view of a driver and a socket of the actuation device of FIG. 8A, the view being taken along the XY plane of FIG. 8A.

### DESCRIPTION

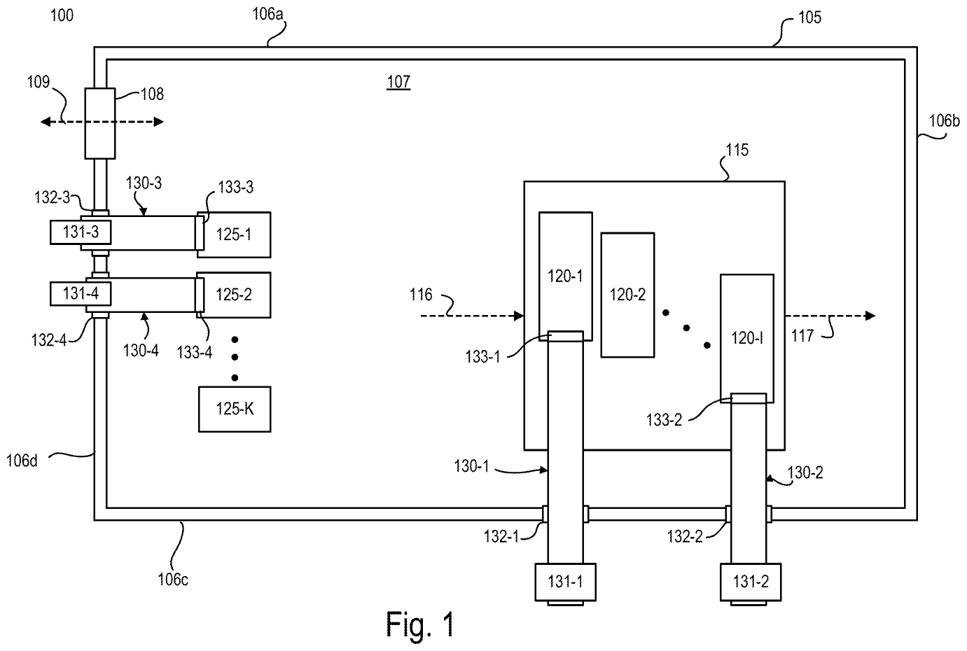

Referring to FIG. 1, an optical pulse stretcher apparatus 100 includes a hermetically-sealed container 105 including one or more walls 106a, 106b, 106c, 106d that define an interior cavity 107. Four walls 106a, 106b, 106c, 106d are shown in the two-dimensional representation of FIG. 1. Nevertheless, the container 105 can be any suitable three-dimensional shape such as a rectangular prism, a cube, or a cylinder, and the number of walls 106a, 106b, 106c, 106d can vary depending on this shape. The interior cavity 107 is maintained, during operation of the optical pulse stretcher apparatus 100, at a controlled environment. For example, the interior cavity 107 can be formed by the hermetically sealed walls 106a, 106b, 106c, 106d. In this way, the interior cavity 107 can be maintained at a particular pressure (such as a pressure below or above atmospheric pressure) or at a particular moisture environment (such as low moisture). As another example, the interior cavity 107 can be configured as a purged environment (such as a nitrogen purged environment). In some implementations, the interior cavity 107 is maintained at a pressure that is about 4-8 pounds per square inch (psi) above atmospheric pressure. For example, if the interior cavity 107 is a purged environment, then the pressure can be maintained at about 18-23 psi.

At least one wall 106d of the container 105 includes one or more windows 108, with each window 108 being configured to pass one or more pulse light beams 109. The pulsed light beam 109 can be an unstretched pulsed light beam or a stretched pulsed light beam. An unstretched pulsed light beam is a light beam that has not passed into or through the apparatus 100 and therefore has not yet been optically stretched by the apparatus 100. A stretched pulsed light beam is a light beam that has been at least partly stretched by passing through the apparatus 100.

The optical pulse stretcher apparatus 100 includes an optical stretcher 115 arranged within the interior cavity 107. The optical stretcher 115 is configured to receive an input pulsed light beam 116 and to generate at least one stretched output pulsed light beam 117. The optical stretcher 115 includes a plurality of optical elements 120-i, where i is the set of numbers 1, 2, . . . I and I is a number greater than 1. The optical pulse stretcher apparatus 100 can also include one or more other optical elements 125-k, where k is a set of numbers 1, 2, . . . K and K is a positive integer, within the interior cavity 107. Each of the optical elements 120-i and 125-k are configured to interact at some point with a pulsed light beam (such as, for example, the pulsed light beam 109, the pulsed light beam 116, or the pulsed light beam 117) within the interior cavity 107.

There is a need to adjust (for example, to align or modify a position or angle of) one or more of the optical elements 120-i, 125-k within the optical pulse stretcher apparatus 100. For example, in order to ensure that the input pulsed light beam 116 properly traverses the optical stretcher 115, one or more of the optical elements 120-i may need to be adjusted. Moreover, such adjustment to an optical element 120-i can occur while the input pulsed light beam 116 is interacting with that optical element 120-i. As another example, the optical pulse stretcher apparatus 100 can include a beam viewing device that is used to find a center of a pulsed light beam within the apparatus 100. The beam viewing device can be configured to translate into and out of a path of a pulsed light beam within the apparatus 100 so that, while out of the path, it does not obstruct or modify the pulsed light beam during normal operation but can be can be moved into the path to thereby enable visualization of the pulsed light beam for diagnostic purposes. Such beam viewing device can be considered an optical element 125-k that needs to be translated into and out of the path of the pulsed light beam.

The apparatus 100 includes one or more through-wall adjusters or actuation devices 130-j, where j is the set of numbers 1, 2, . . . J and J is a positive integer. Each actuation device 130-j extends through the wall (such as the wall 106d). In this way, at one end, the actuation device 130-j is physically within the interior cavity 107, while at another opposite end, the actuation device 130-j is external to the interior cavity 107. Each actuation device 130-j is associated with and physically communicates with an optical element 120-i, 125-k that at some moment in time needs to be adjusted. Thus, some of the optical elements 120-i, 125-k may not be associated with an actuation device 130-j. In FIG. 1, optical element 120-1 is associated with actuation device 130-1, optical element 120-1 is associated with actuation device 130-2, optical element 125-1 is associated with actuation device 130-3, and optical element 125-2 is associated with actuation device 130-4. Although four actuation devices 130-1, 130-2, 130-3, 130-4 are shown in FIG. 1, there can be fewer than or more than four actuation devices 130-j. Each actuation device 130-j includes a respective adjustment mechanism 131-j external to the hermetically-sealed container 105. Thus, the actuation device 130-1 includes the adjustment mechanism 131-1; the actuation device 130-2 includes the adjustment mechanism 131-2; the actuation device 130-3 includes the adjustment mechanism 131-3; and the actuation device 130-4 includes the adjustment mechanism 131-4.

The adjustment mechanism 131-j enables adjustment of one or more physical properties of the optical element (120-i or 125-k) that is in physical communication with the actuation device 130-j without disrupting the controlled environment within the interior cavity 107. That is, the adjustment mechanism 130-j enables the associated optical element 120-i, 125-k to be adjusted without requiring the opening of the hermetically-sealed container 105.

In prior adjustment procedures that require opening of the hermetically-sealed container 105, serviceability of the apparatus 100 is time consuming and complex. For example, it can be challenging for a field service engineer to directly access the optical element 120-i, 125-k in order to make adjustments using these prior procedures. This is because space within the interior cavity 107 is limited and the geometric placement of the various optical elements 120-i, 125-k can make access difficult. Additionally, while the container 105 is open (during these prior adjustment procedures), the pulsed light beam 109 is usually operated at a lower repetition rate, and this makes it more difficult for the field service engineer to quickly and accurately perform the needed adjustments to the optical element 120-i, 125-k. Lastly, because the container 105 is hermetically-sealed and the interior cavity 107 can use a purge gas, extra time is required to remove the purge gas, open the container 105, perform the adjustments, reseal the container 105, and re-introduce the purge gas to the interior cavity 107.

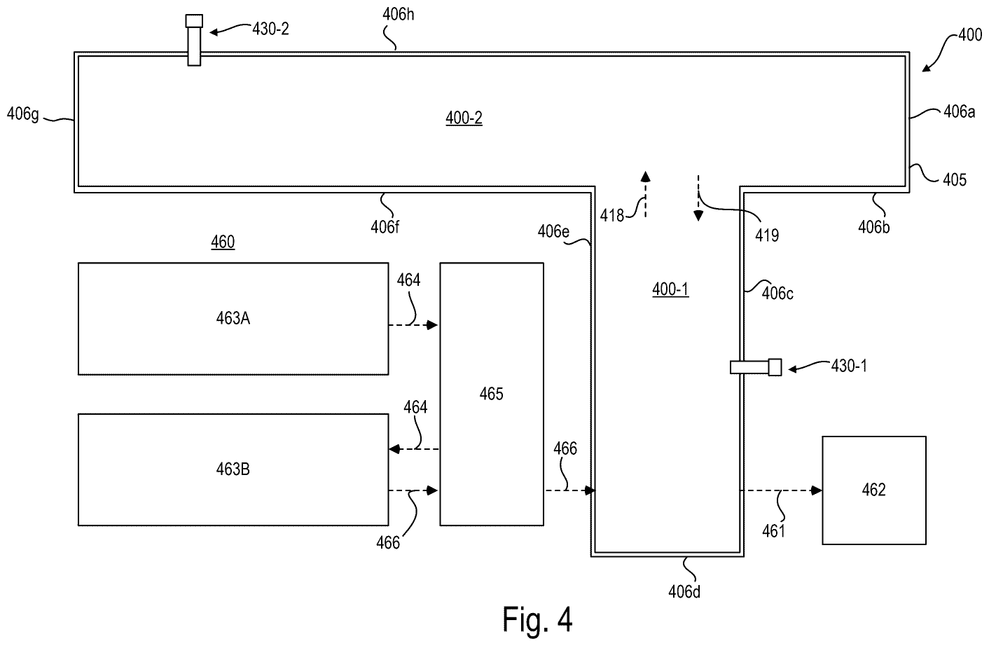

By contrast, by using the actuation device 130-j (and adjustment mechanism 131-j), the time and complexity to service the optical pulse stretcher apparatus 100 is reduced because the steps for opening the container 105 and then the subsequently closing the container 105 are not needed. Additionally, the pulsed light beam 109 that is received by the optical pulse stretcher apparatus 100 through the window 108 can be produced at a high repetition rate during adjustment of the optical element 120-i, 125-k. By using a pulsed light beam 109 at a high repetition rate during adjustment, it is possible to perform a speedier and/or more accurate adjustment because it is easier to visualize the pulsed light beam 109 as it interacts with the optical element 120-i, 125-k. This is particularly important if the optical element 125-k includes, for example, a fluorescent screen, where fluorescence is produced when interacting with a pulsed light beam 109. By operating at a high repetition rate, the adjustment process can be adapted as the fluorescent screen (of the optical element 125-k) ages; for example, the repetition rate of the pulsed light beam 109 can be adjusted depending on the age of the fluorescent screen to accommodate this deterioration. A high repetition rate can be a repetition rate that is greater than 50 Hertz (Hz), greater than 100 Hz, greater than 500 Hz, greater than 1000 Hz, or greater than 3000 Hz. In some implementations, a high repetition rate is a rate that extends up to 6 kilohertz (kHz). In some implementations, a high repetition rate is the repetition rate that required by a downstream output apparatus (such as a repetition rate required by a photolithography exposure apparatus 462 of FIG. 4). Moreover, the optical element 120-i, 125-k can be adjusted remotely by the field service engineer, without requiring the field service engineer to directly and often awkwardly (as noted above) access to the optical element 120-i, 125-k. And, the optical element 120-i, 125-k can be adjusted while it is within the controlled environment of the interior cavity 107, and if a purge gas is used, then it can be maintained while the optical element 120-i, 125-k is being adjusted.

The actuation devices 130-j are designed to operate in the controlled environment of the interior cavity 107. For example, if a purge gas is used during operation go the apparatus 100, then the portions of the actuation devices 130-j inside the interior cavity 107 are compatible with that purge gas. Because a purge gas is used and the environment is controlled, the actuation devices 130-j operate without the use of a lubricant or a friction-reducing material such as Teflon or leaded metals. Additionally, by avoiding the use of lubricants and friction-reducing materials, outgassing at the actuation devices 130-j is reduced. Outgassing, which can occur due to light scattering that occurs at the lubricants or friction-reducing materials, can degrade the performance or lifetime of the optical elements 120-i, 125-k.

Because each actuation device 130-j extends between the interior cavity 107, at the location where the actuation device 130-j physically communicates with the respective optical element 120-i, 125-k, and the outside of the container 105, the actuation device 130-j also needs to provide a seal at an interface 132-j between the actuation device 130-j and the wall in which it is mounted. For example, a first seal is formed at the interface 132-1 between the actuation device 130-1 and the wall 106c; a second seal is formed at the interface 132-2 between the actuation device 130-2 and the wall 106c; a third seal is formed at the interface 132-3 between the actuation device 130-3 and the wall 106d; and a fourth seal is formed at the interface 132-4 between the actuation device 130-4 and the wall 106d.

As mentioned above, each actuation device 130-j physically communicates with its respective optical element 120-i, 125-k within the interior cavity 107. In order to enable this physical communication, each actuation device 130-j includes a driver 133-j that is in physical contact with a region or portion of the optical element 120-i, 125-k. Thus, in the example of FIG. 1, the actuation device 130-1 includes a driver 133-1 in physical contact with a region or portion of the optical element 120-1; the actuation device 130-2 includes a driver 133-2 in physical contact with a region or portion of the optical element 120-I; the actuation device 130-3 includes a driver 133-3 in physical contact with a region or portion of the optical element 125-1; and the actuation device 130-4 includes a driver 133-4 in physical contact with a region or portion of the optical element 125-2. This driver 133-j can be an device that is able to make physical contact with and maintain physical contact with the region or portion of the optical element 120-i, 125-k.

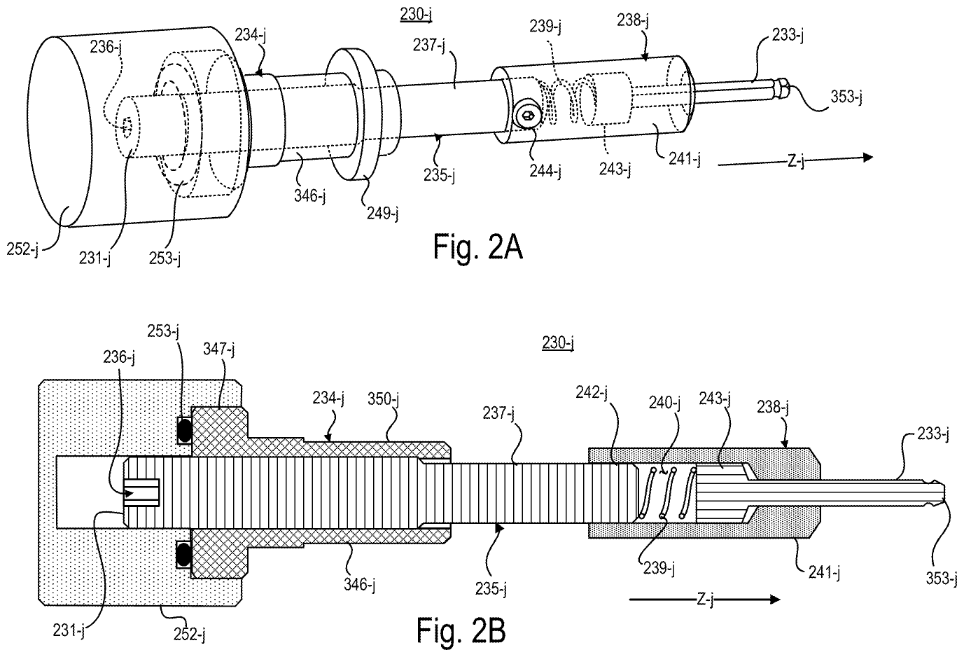

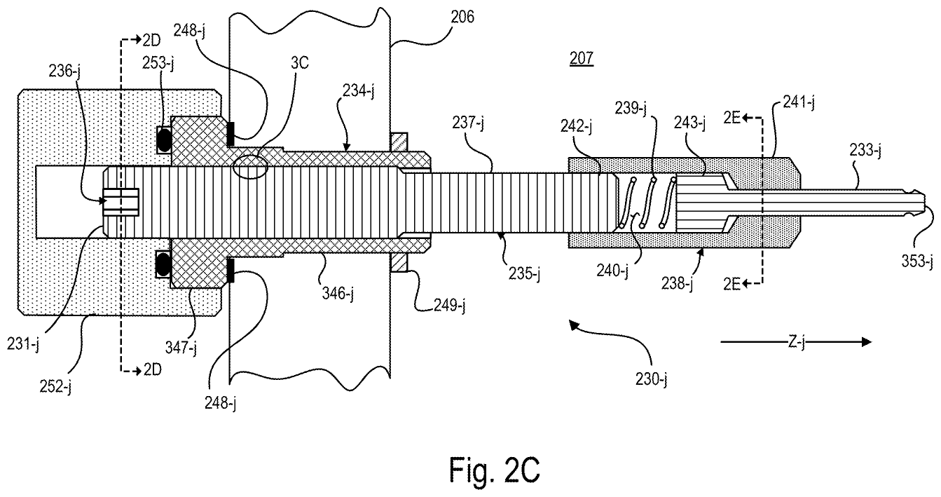

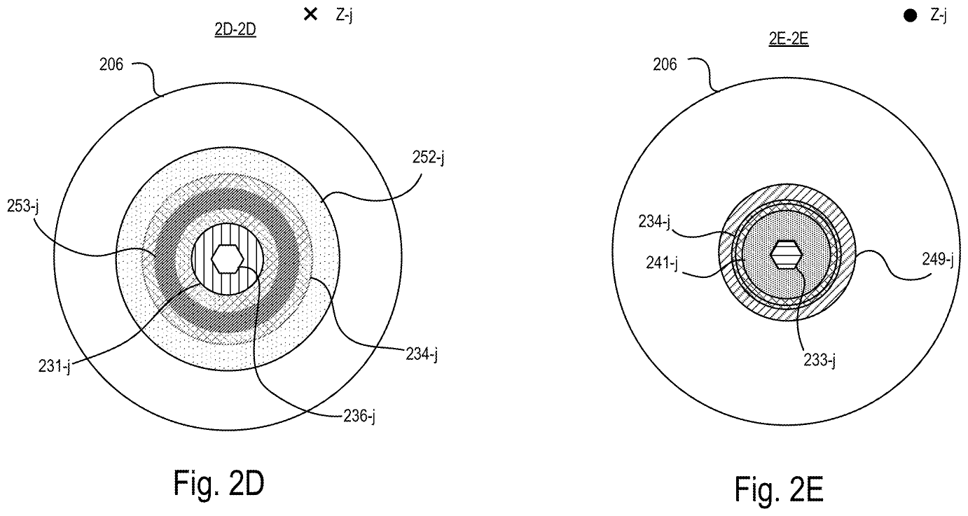

Referring to FIGS. 2A-2E, an implementation 230-j of the actuation device 130-j is shown. In FIGS. 2C-2E, the actuation device 230-j is shown mounted to a wall 206 of a hermetically-sealed container such as the container 105. The actuation device 230-j includes an adjustment mechanism 231-j that is positioned external to an interior cavity 207 (FIG. 2C) when the actuation device 230-j is mounted to the wall 206. The actuation device 230-j includes a driver 233-j that is inside the interior cavity 207 when the actuation device 230-j is mounted to the wall 206. As discussed above, the driver 233-j engages with (is in physical contact with) a region or portion of an optical element 120-i or 125-k within the container 105. In this way, the adjustment mechanism 231-j is accessible from outside the container 105, and the driver 233-j can be controlled (to thereby made adjustments to the optical element) without requiring access to the interior cavity 207.

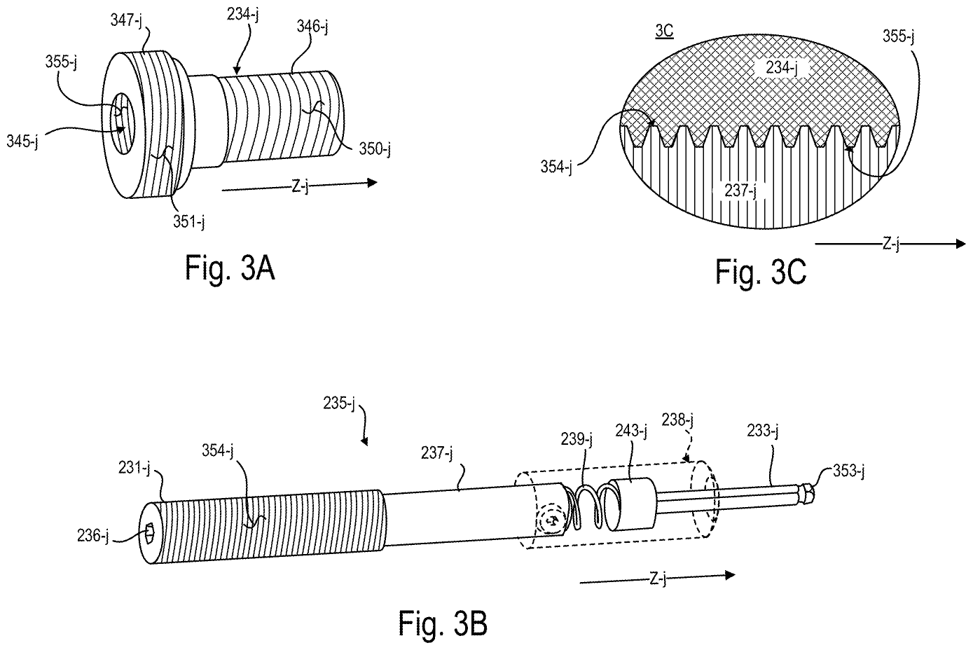

The adjustment mechanism 231-j is a part of and at a first end of a driving element 235-j. The driving element 235-j extends through a central opening 345-j (FIG. 3A) of a bushing 234-j. The adjustment mechanism 231-j includes a rotational element 236-j that enables the adjustment mechanism 231-j to be rotated relative to the bushing 234-j. In this implementation, the rotational element 236-j is a shaped opening or concavity (specifically, a hexagonal socket) defined at the end of the adjustment mechanism 231-j, and the adjustment mechanism 231-j is designed like a screw. The adjustment mechanism 231-j is rotated when an appropriately-shaped drive element is inserted into the shaped opening 236-j and then rotated. For example, if the shaped opening 236-j is a hexagonal socket then a hex-head screw driver or Allen wrench can be inserted into the hexagonal socket 236-j and then rotated to thereby rotate the adjustment mechanism 231-j relative to the bushing 234-j.

The driving element 235-j is configured to move relative to the bushing 234-j along an axial direction Z-j, while the bushing 234-j is hermetically sealed within and fixed to the wall 206 (FIG. 2C). The driving element 235-j includes a body 237-j that extends axially (that is, along the axial direction Z-j) along the central opening 345-j (FIG. 3A) of the bushing 234-j and defines the direction of translation that is applied to the driver 233-j. The driving element 235-j includes, at a second end, the driver 233-j. The driving element 235-j also includes a biasing apparatus 238-j configured to bias the driver 233-j in the positive Z-j direction so that the driver 233-j remains engaged with the region or portion of the optical element 120-i or 125-k while the driver 233-j is adjusting the optical element 120-i or 125-k. The biasing apparatus 238-j includes a biasing device 239-j (such as a spring) mounted within a cavity 240-j of a coupler 241-j. The cavity 240-j receives a second end 242-j of the body 237-j as well as a base 243-j of the driver 233-j, and the biasing device 239-j is mounted between the base 243-j and the second end 242-j. The biasing device 239-j is biased in the positive Z-j direction so that it pushes the base 243-j and therefore the driver 233-j in the positive Z-j direction. Because of this biasing function, the driver 233-j is in elastic engagement with the adjustment mechanism 231-j. And, the driving element 235-j remains in physical communication with the optical element (such as optical element 120-i, 125-k) during all range of motions of the driving element 235-j relative to the bushing 234-j. The coupler 241-j is fixed to the second end 242-j of the body 237-j by way of a fixing device 244-j such as a set screw.

FIG. 3A shows the bushing 234-j separated from other components of the actuation device 230-j. The bushing 234-j includes a cylindrically-shaped body 346-j that defines the central opening 345-j, both the body 346-j and the central opening 345-j extending along the axial direction Z-j and the central opening 345-j extending through the bushing 234-j. The bushing 234-j also includes a cylindrically-shaped flange 347-j that extends from the body 346-j. The flange 347-j is configured to enable the bushing 234-j to be hermetically sealed to the wall 206, as shown in FIG. 2C. Specifically, a seal is formed at the interface between the wall 206 and the radial surface of the flange 347-j, such seal preventing leakage of matter between the interior cavity 207 and exterior of the container 105. In this example, the seal is formed from a gasket 248-j sandwiched between the radial surface of the flange 347-j and the outer surface of the wall 206. The gasket 248-j is compressed when the flange 347-j and the wall 206 are pressed into each other (along the axial direction Z-j). For example, the body 346-j can include an outer threaded surface 350-j (shown in FIG. 3A) and a threaded nut 249-j (FIG. 2C) placed around the body 346-j can be turned relative to the outer threaded surface 350-j to press the wall 206 and the flange 347-j together and to thereby compress the gasket 248-j and engage the seal. This seal (at the gasket 248-j) prevents purge gas (such as nitrogen or N₂ gas) from escaping from the interior cavity 207 along the path between the bushing 234-j and the wall 206.

In some implementations, an additional seal can be formed between the bushing 234-j and the driving element 235-j. To this end, the flange 347-j of the bushing 234-j includes an outer threaded surface 351-j (shown in FIG. 3A) that mates with an inner threaded surface of a cap 252-j (shown in FIGS. 2A-2C). The seal can be formed at the interface between the cap 252-j and the outer facing radial surface of the flange 347-j. Specifically, a screw thread seal is formed when the cap 252-j is screwed onto the flange 347-j and as the cap 252-j is tightened, an O-ring 253-j placed at the interface between the outer radial surface of the flange 347-j and the cap 252-j is compressed to thereby form the seal. This second or additional seal therefore relies on the placement of the cap 252-j over the flange 347-j. Thus, in order to access the adjustment mechanism 231-j, the cap 252-j needs to be removed.

FIG. 3B shows the driving element 235-j separated from other components of the actuation device 230-j. The biasing device 239-j is between the second end 242-j of the body 237-j and the base 243-j of the driver 233-j. The driver 233-j extends along the axial direction Z-j and includes a tip 353-j that directly physical contacts the region or portion of the optical element 120-i, 125-k. The base 243-j of the driver 233-j has a generally cylindrical shape that has a diameter that is smaller than the diameter of the cavity 240-j and is enabled to move along the axial direction Z-j within the cavity 240-j. The tip 353-j of the driver 233-j has a geometric shape that is complementary to a geometric shape of the region or portion of the optical element 120-i, 125-k that it is in physical contact with. Because of this, the tip 353-j is able to maintain a frictional engagement with the region or portion of the optical element 120-i, 125-k. For example, the tip 353-j can be hexagonal in shape and the region or portion of the optical element 120-i, 125-k that is in physical contact with the tip 353-j can be a hexagonally-shaped socket.

As shown in FIGS. 3B and 3C, the body 237-j includes a threaded outer surface 354-j. This threaded outer surface 354-j mates with a threaded inner surface 355-j (shown in FIG. 3A) of the central opening 345-j of the bushing 234-j. Thus, the interface between the body 237-j and the bushing 234-j is a threaded interface. Because the bushing 234-j is fixed within an opening of the wall 206, when the cap 252-j is removed, and the adjustment mechanism 231-j is engaged (such as by turning an Allen wrench inserted into hexagonal socket 236-j), the entire body 237-i is rotated relative to the bushing 234-j, which causes the body 237-i to also be translated along the axial direction Z-j relative to the bushing 234-j (and relative to the wall 206). The threads of the threaded outer surface 354-j and the threads of the threaded inner surface 355-j can be made rounded instead of sharp. In order to obtain rounded threads, the threads are formed by rolling the surface (surface 354-j or 355-j) with a die instead of cutting the threads on a machine. In some implementations, the threads at the surfaces 354-j and 355-j can have a fine pitch, such as a pitch of 80-100 teeth per inch.

Because they are at least partly within the interior cavity 207, which is a controlled environment, the bushing 234-j and the components of the adjustment mechanism 231-j (components such as the body 237-j, the coupler 241-j, the biasing device 239-j, and the driver 233-j) are made of materials that are non-reactive to any materials within the interior cavity 107/207. Additionally, the bushing 234-j and the components of the adjustment mechanism 231-j that move relative to each other (such as the body 237-i) should be made of a material that enables the relative motion while also ensuring that friction is maintained below an acceptable level. Additionally, the interface between the body 237-j and the bushing 234-j (shown in detail in FIG. 3C) needs to operate (that is, the body 237-j needs to be able to move relative to the bushing 234-j) without the use of lubricants, which can interfere with the controlled environment within the interior cavity 107/207. When considering these factors, in some implementations, the bushing 234-j and the components of the adjustment mechanism 231-j can be made of non-leaded metals or non-leaded metal alloys. For example, the bushing 234-j can be made of phosphor bronze (such as UNS C51000 or H04 Temper). If the adjustment mechanism 231-j is a screw, then it can be made of stainless steel, such as stainless steel type 303 (UNS S30300).

Referring to FIG. 4, an implementation 400 of the optical pulse stretcher apparatus 100 is a part of a pulsed light source 460. The light source 460 can be used as a part of a lithographic apparatus to supply a pulsed light beam 461 to a photolithography exposure apparatus 462 for generating a circuit pattern on a target portion of a substrate (or wafer). In some implementations, the light source 460 is a deep ultraviolet (DUV) light source and the light beam 461 has a wavelength in the DUV wavelength range, which can include wavelengths from, for example, about 100 nanometers (nm) to about 400 nm. As illustrated in FIG. 4, the light source 460 can be a dual-stage light source that includes a first stage 463A and a second stage 463B. The first stage 463A can include a master oscillator (MO) that produces a first pulsed light beam 464, which is passed to the second stage 463B by way of optical elements 465 that includes relay optics. The second stage 463B can include a power amplifier (PA) that receives the first pulsed light beam 464 and optically amplifies the first pulsed light beam 464 to form a second pulsed light beam 466 that is directed to the optical pulse stretcher apparatus 400.

The first stage 463A can include, for example, an MO chamber module, in which electrical discharges between electrodes (not shown) can cause lasing gas discharges in a lasing gas to create an inverted population of high energy molecules, such as including argon, krypton, or xenon to produce relatively broad band radiation. This radiation is line narrowed to a relatively very narrow bandwidth and center wavelength selected in a line narrowing module (‘LNM’) within the first stage 463A. The first stage 463A can also include an MO output coupler (MO OC), which can include a partially reflective mirror, forming, with a reflective grating in the LNM, an oscillator cavity in which the first stage 463A oscillates to form the first pulsed light beam 464. The first stage 463A can also include other components such as a line-center analysis module (LAM).

The optical elements 465 can include an MO wavefront engineering box (WEB) that serves to redirect the first pulsed light beam 464 toward the second stage 463B. The optical elements 465 can also include, for example, beam expansion optical elements with, for example, a multi prism beam expander (not shown) and coherence busting, for example, in the form of an optical delay path (not shown).

The second stage 463B includes a PA chamber module, which is also an oscillator, for example, formed by injection of the first pulsed light beam 464 and output coupling optics and can be redirected back through a gain medium in the PA chamber by way of a beam reverser. The output coupling optics can incorporate a partially reflective input/output coupler and a maximally reflective mirror for the nominal operating wavelength (which can be at around 193 nm for an ArF system) and one or more prisms. The second stage 463B optically amplifies the first pulsed light beam 464 to form the second pulsed light beam 466.

Each of the MO chamber module (of the first stage 463A) and the PA chamber module (of the second stage 463B) can be a part of a gas discharge light source such as an excimer light source. In such light sources, the MO chamber module and the PA chamber module each contain a gas mixture, which includes a combination of one or more noble gases, which can include argon, krypton, or xenon, and a reactive gas, which can include fluorine or chlorine as the gain medium. Thus, for example, the gain medium in each module can include argon fluoride (ArF), krypton fluoride (KrF), or xenon chloride (XeCl). If the gain medium includes argon fluoride, then the wavelength of the pulsed light beam 461 is about 193 nm and if the gain medium includes krypton fluoride, then the wavelength of the pulsed light beam 461 is about 248 nm. The size of the microelectronic features patterned on the wafer (in the photolithography exposure apparatus 462 depends on the wavelength of the pulsed light beam 461, with a lower wavelength resulting in a smaller minimum feature size.

The second pulsed light beam 466 is input to the optical pulse stretcher apparatus 400, where copies of the second pulsed light beam 466 are delayed and recombined to thereby reduce speckle in the pulsed light beam 461 that is directed to photolithography exposure apparatus 462.

Examples of a dual-stage light source 460 and an optical pulse stretcher apparatus 400 are described in WO 2021/076658, published on Apr. 22, 2021 by applicant Cymer, LLC, the disclosure of which is incorporated herein by reference in its entirety.

In some implementations, the optical pulse stretcher apparatus 400 includes a single pulse stretcher. In other implementations, the optical pulse stretcher apparatus 400 includes several stages of pulse stretchers. For example, a pulse stretcher can include a plurality (at least two) of concave mirrors arranged relative to each other to form a confocal resonator. In some implementations, as discussed in detail in WO 2021/076658, the optical pulse stretcher apparatus 400 includes a first optical pulse stretcher device 400-1 and a second optical pulse stretcher device 400-2 arranged as a series of stacked optical pulse stretcher devices. In these implementations, the first optical pulse stretcher device 400-1 receives the second pulsed light beam 466 and delays and recombines copies of the second pulsed light beam 466 to generate a first stretched pulsed light beam 418. This first stretched pulsed light beam 418 is then input to the second optical pulse stretcher device 400-2, which delays and recombines copies of the first stretched pulsed light beam 418 to generate a second stretched pulsed light beam 419. This second stretched pulsed light beam 419 is input to the first optical pulse stretcher device 400-1, where it is then redirected out as the pulsed light beam 461.

The optical pulse stretcher apparatus 400 includes a hermetically-sealed container 405 that includes a plurality of walls 406a, 406b, 406c, 406d, 406e, 406f, 406g, 406h that together define the interior cavity that houses optical components or elements of the devices 400-1 and 400-2. For simplicity, FIG. 4 shows a two-dimensional rendering of the container 405 with eight walls but the container 405 is three dimensional and can include walls that extend in other directions or parallel with the page. Like the optical pulse stretcher apparatus 100, apparatus 400 includes one or more through-wall adjusters or actuation devices 430-j. Two actuation devices 430-1 and 430-2 are shown in FIG. 4, with the actuation device 430-1 associated with an optical element (not shown in FIG. 4) within the first optical pulse stretcher device 400-1 and the actuation device 430-2 associated with an optical element (not shown in FIG. 4) within the second optical pulse stretcher device 400-2. The optical pulse stretcher apparatus 400 can include fewer than or more than two actuation devices 430-j and each of the optical pulse stretcher devices 400-1, 400-2 can include one or more respective actuation devices 430-j.

Each optical pulse stretcher device 400-1, 400-2 can include one or more optical pulse stretchers, with each optical pulse stretcher including one or more confocal resonators. A confocal resonator includes reflecting surfaces that generally face each other and are arranged relative to each other so that a pulsed light beam (such as the second pulsed light beam 466 or the first stretched pulsed light beam 418) is reflected back and forth in a region between the reflecting surfaces.

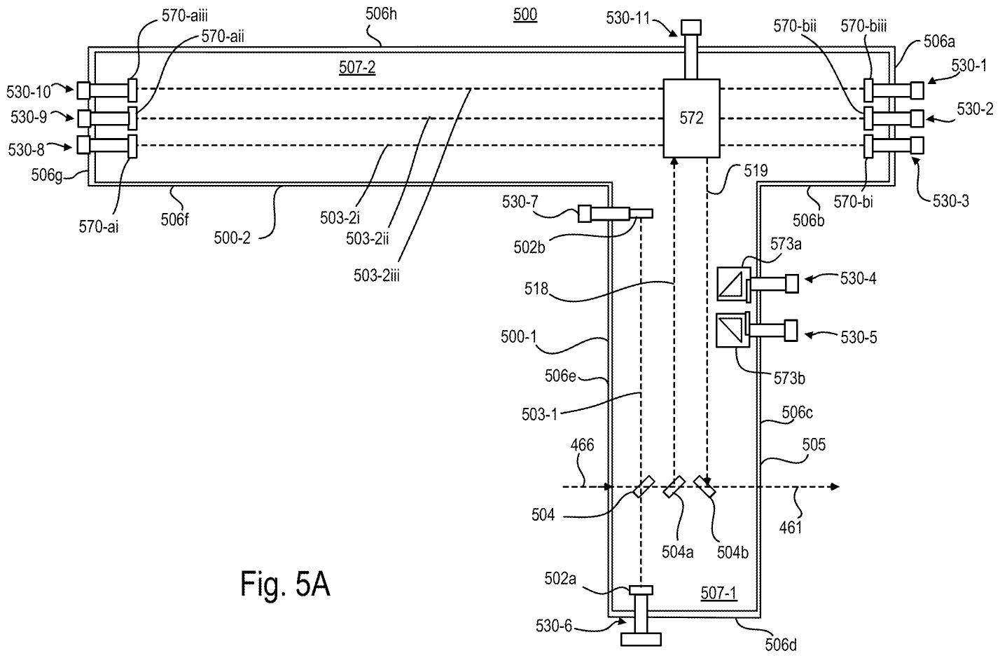

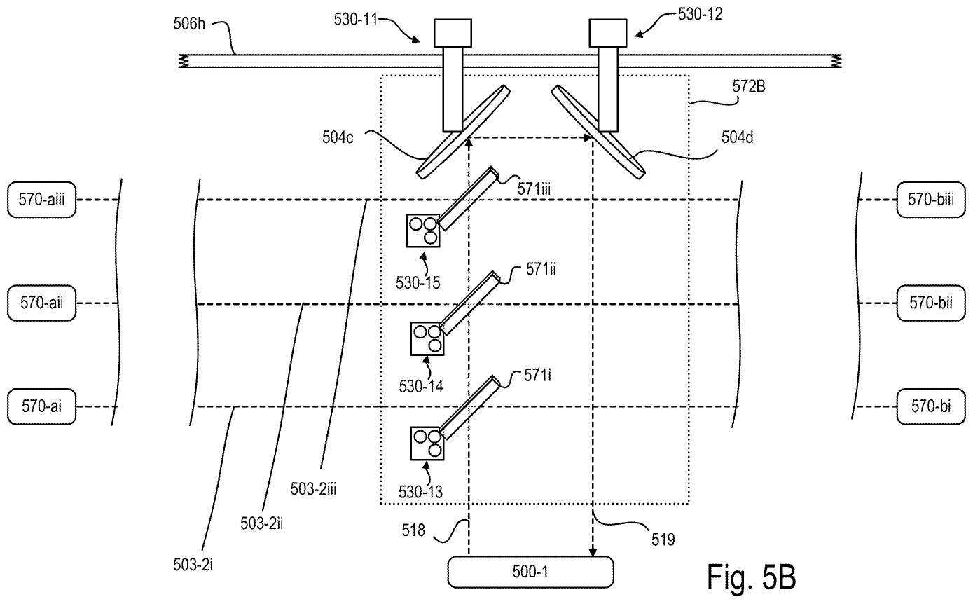

Referring to FIG. 5A, an implementation 500 of the optical pulse stretcher apparatus 400 is shown. The optical pulse stretcher apparatus 500 includes a first optical pulse stretcher device 500-1 and a second optical pulse stretcher device 500-2 arranged as a series of stacked optical pulse stretcher devices. In these implementations, the first optical pulse stretcher device 500-1 receives the second pulsed light beam 466, and delays and recombines copies of the second pulsed light beam 466 to generate a first stretched pulsed light beam 518. This first stretched pulsed light beam 518 is then input to the second optical pulse stretcher device 500-2, which delays and recombines copies of the first stretched pulsed light beam 518 to generate a second stretched pulsed light beam 519. This second stretched pulsed light beam 519 is input to the first optical pulse stretcher device 500-1, where it is then redirected out as the pulsed light beam 461.

The first optical pulse stretcher device 500-1 includes, within its interior cavity 507-1, a least one optical pulse stretcher 503-1 that includes at least two opposing mirrors 502a, 502b that produce reflections between them and define a confocal resonator. For example, the optical pulse stretcher 503-1 can include a first single mirror 502a and a second single mirror 502b to produce two reflections of delayed portions of the second pulsed light beam 466. As another example, the optical pulse stretcher 503-1 can include two first mirrors 502a and two second mirrors 502b that produce four reflections of delayed portions of the second pulsed light beam 466. The mirrors 502a, 502b can be separated from each other by a large enough physical distance to enable the desired optical delays. In some implementations, the mirrors 502a, 502b are separated by a physical distance of, for example, about 1 meter (m) to about 3 m. Such physical distance can provide an optical delay of about 30 nanoseconds (ns) to about 50 ns. The mirrors 502a, 502b can be circular and concave mirrors. Additionally, the first optical pulse stretcher device 500-1 can include other optical elements. For example, a beam splitter 504 is positioned on the path of the second pulsed light beam 466 to split off a portion of the second pulsed light beam 466 toward the optical pulse stretcher 503-1. A pair of beam splitters 504a, 504b can be positioned to split off the first stretched pulsed light beam 518 to the second optical pulse stretcher device 500-2 and then recombine the second stretched pulsed light beam 519 from the second optical pulse stretcher device 500-2.

The second optical pulse stretcher device 500-2 includes, within its interior cavity 507-2, one or more confocal optical pulse stretchers. In the example shown, there are three confocal optical pulse stretchers 503-2i, 503-2ii, 503-2iii. Each of the optical pulse stretchers 503-2i, 503-2ii, 503-2iii includes at least two respective opposing mirrors 570-ai, 570-bi; 570-aii, 570-bii; 570-aiii, 570-biii. Although two opposing mirrors are shown in each pulse stretcher 503-2i, 503-2ii, 503-2iii, it is possible for each pulse stretcher 503-2i, 503-2ii, 503-2iii to include more than two opposing mirrors.

The second optical pulse stretcher device 500-2 also includes an optical arrangement 572 that is configured to receive the first stretched pulsed light beam 518, split the first stretched pulsed light beam 518 into portions, redirect the split portions into one or more of the pulse stretchers 503-2i, 503-2ii, 503-2iii, and recombine the split portions that have been delayed to form the second stretched pulsed light beam 519. The optical arrangement 572 therefore includes one or more beam splitters and fold mirrors.

Referring to FIG. 5B, an implementation 572B of the optical arrangement 572 is shown. The optical arrangement 572B includes three beamsplitters 571i, 571ii, 57 liii placed along the path of the first stretched pulsed light beam 518, with each beamsplitter 571i, 571ii, 571iii configured to pick off a portion of the first stretched pulsed light beam 518 and direct that portion into the respective confocal optical pulse stretcher 503-2i, 503-2ii, 503-2iii. The optical arrangement 572B also include two fold mirrors 504c, 505d arranged to direct the second stretched pulsed light beam 519 (formed from passing the first stretched pulsed light beam 518 portions through each of the confocal optical pulse stretchers 503-2i, 503-2ii, 503-2iii) back toward the first optical pulse stretcher device 500-1.

Referring again to FIG. 5A, the optical pulse stretcher apparatus 500 includes a hermetically-sealed container 505 that includes a plurality of walls 506a, 506b, 506c, 506d, 506e, 506f, 506g, 506h that together define the interior cavity that houses optical components or elements of the devices 500-1 and 500-2. For simplicity, FIG. 5A shows a two-dimensional rendering of the container 505 with eight walls but the container 505 is three dimensional and can include walls that extend in other directions or parallel with the page and the container 505 can include different sections that are connected together.

The optical pulse stretcher apparatus 500 can also include optical elements 573a, 573b that are used for alignment of other optical elements within the optical pulse stretcher apparatus 500. In the example of FIG. 5A, optical element 573a is an alignment apparatus configured to selectively interact with the first stretched pulsed light beam 518 and optical element 573b is an alignment apparatus configured to selectively interact with the second stretched pulsed light beam 519. Additional alignment apparatuses can be used at other locations along the path of the light beams that travel through the optical pulse stretcher apparatus 500. The alignment apparatus 573a is used to visualize the first stretched pulsed light beam 518 and the alignment apparatus 573b is used to visualize the second stretched pulsed light beam 519. These visualizations enable an engineer to determine the pathways of the light beams and make adjustments to other components within the apparatus 500 to ensure that the light beams are aligned with the optical elements. During normal operation of the apparatus 500, the apparatus 500 optically stretches the second pulsed light beam 466 to form the pulsed light beam 461. During normal operation of the apparatus 500, the alignment apparatus 573a is not interacting with the first stretched pulsed light beam 518 and the alignment apparatus 573b is not interacting with the second stretched pulsed light beam 519, as shown in FIG. 5A. On the other hand, during visualization operation, when there is a need to visualize the light beam 518, the alignment apparatus 573a is moved and thereby inserted into the path of the light beam 518 and when there is a need to visualize the light beam 519, the alignment apparatus 573b is moved and thereby inserted into the path of the light beam 519.

Like the optical pulse stretcher apparatus 100, the apparatus 500 includes one or more through-wall adjusters or actuation devices 530-j. Actuation devices 530-1, 530-2, 530-3, 530-8, 530-9, 530-10 are associated with, respectively, mirrors 570-biii, 570-bii, 570-bi, 570-ai, 570-aii, 570-aiii of the optical pulse stretchers 503-2i, 503-2ii, 503-2iii. Actuation devices 530-4 and 530-5 are associated with, respectively, alignment apparatuses 573a and 573b. Actuation devices 530-6 and 530-7 are associated with, respectively, mirrors 502b and 502a of the optical pulse stretcher 503-1. Lastly, at least one actuation device 530-11 is associated with an optical element within the optical arrangement 572. The actuation devices 530-1, 530-2, 530-3 are mounted as through-wall adjusters in the wall 506a; the actuation devices 530-4 and 530-5 are mounted as through-wall adjusters in the wall 506c; the actuation device 530-6 is mounted as a through-wall adjuster in the wall 506d; the actuation device 530-7 is mounted as a through-wall adjuster in the wall 506e; the actuation devices 530-8, 530-9, 530-10 are mounted as through-wall adjusters in the wall 506g; and the actuation device 530-11 is mounted as a through-wall adjuster in the wall 506h. The optical pulse stretcher apparatus 500 can include fewer than or more than eleven actuation devices 530-j and each of the optical pulse stretcher devices 500-1, 500-2 can include one or more respective actuation devices 530-j.

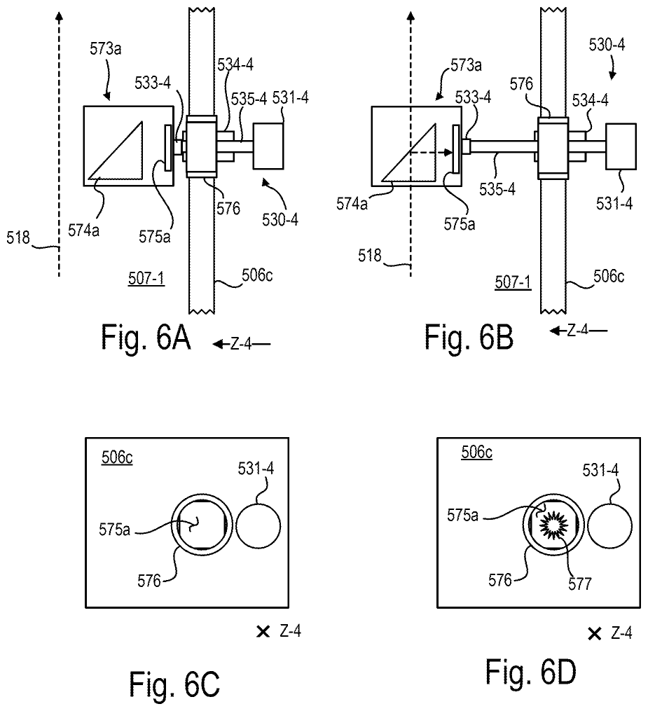

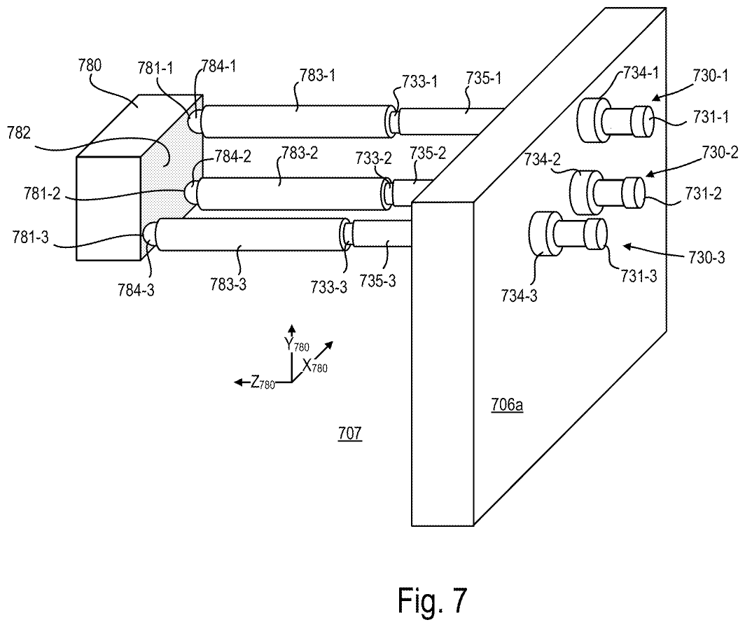

Referring to FIG. 5B, there can be more than one actuation device 530-11 mounted as a through-wall adjuster in a wall to access one or more of the optical components within the optical arrangement 572B. In this implementation, two actuation devices 530-11, 530-12 are mounted at wall 506h for control and adjustment of respective mirrors 504c, 504d. Moreover, actuation devices 530-13, 530-14, 530-15 are mounted (along a different wall that is parallel with the page) to respective beamsplitters 571i, 571ii, 571iii. The actuation devices 530-11, 530-12 can be mounted to respective fold mirrors 504c, 504d in a manner similar to what is shown in FIGS. 6A-6D or as shown in FIG. 7. The actuation devices 530-13, 530-14, 530-15 can be arranged relative to the respective beam splitter 571i, 571ii, 571iii in a manner similar to what is shown in FIG. 7. Thus, as discussed below with respect to FIG. 7, there may be two actuation devices arranged for each beamsplitter 571i, 571ii, 571iii to provide both tip and tilt adjustment to each beamsplitter 571i, 571ii, 571iii.

Referring to FIGS. 6A-6D, an implementation of the actuation device 530-4 and associated alignment apparatus 573a are shown in side cross-sectional view (FIGS. 6A and 6B) and in plan view looking toward wall 506c (FIGS. 6C and 6D). FIGS. 6A and 6C show normal operation and FIGS. 6B and 6D show visualization operation. In particular, in FIGS. 6A and 6C, the alignment apparatus 573a is out of the path of the light beam 518 while in FIGS. 6B and 6D, the alignment apparatus 573a is placed in the path of the light beam 518. The alignment apparatus 573a includes a refracting element such as a prism 574a and a visualization device such as a fluorescent screen 575a. The engineer can view the fluorescent screen 575a through a viewport 576 placed in the wall 506c near the fluorescent screen 575a. The viewport 576 is hermetically sealed to the wall 506c and enables the visualization of the fluorescent screen 575a from outside the container 505. The viewport 576 includes a material that is transparent to light that is produced at the fluorescent screen 575a. The fluorescent screen 575a is fixed in relationship to the prism 574a and thus they are moveable together under control of the actuation device 530-4. The actuation device 530-4 includes an adjustment mechanism 531-4 that is external to the interior cavity 507-1 and positioned at one end of a driving element 535-4. Another end of the driving element 535-4 includes the driver 533-4, which physically engages with the alignment apparatus 573a (for example, with a wall of the alignment apparatus 573a). When the adjustment mechanism 531-4 is turned, the driving element 535-4 is adjusted (for example, translated along the Z-4 axis) relative to a bushing 534-4 that is fixed to the wall 506c to thereby move the alignment apparatus 573a between the non-interacting position in FIGS. 6A and 6C and the interacting position in FIGS. 6B and 6D. When the alignment apparatus 573a is inserted into the path of the light beam 518, a portion 518p of the light beam 518 is redirected by the prism 574a toward the fluorescent screen 575a, where the light causes materials within the screen 575a to fluoresce and the light 577 that is produced from the fluorescence is visualized through the viewport 576, as shown in FIG. 6D. By visualizing the light 577, the engineer is able to find a center of the light beam 518, and to better make adjustments to move the center of the light beam 518 if needed.

Referring to FIG. 7, as discussed above, the optical element that is able to be adjusted with an actuation device 130-j can be a mirror such as a concave mirror or it can be another optical element such as a beamsplitter (such as shown in FIG. 5B). For example, the optical element can be a concave mirror 780 within an interior cavity 707 defined by a plurality of walls, with a portion of one wall 706a being shown in FIG. 7. The concave mirror 780 can be an optical element 120-i within an optical stretcher 115 such as any of the concave mirrors 570-ai, 570-aii, 570-aii, 570bi, 570bii, 570biii within the first optical pulse stretcher device 500-1 (FIG. 5A) or any of the mirrors 502a, 502b within the second optical pulse stretcher device 500-2 (FIG. 5A). In other implementations, the concave mirror 780 is a beamsplitter such as those shown in FIG. 5B.

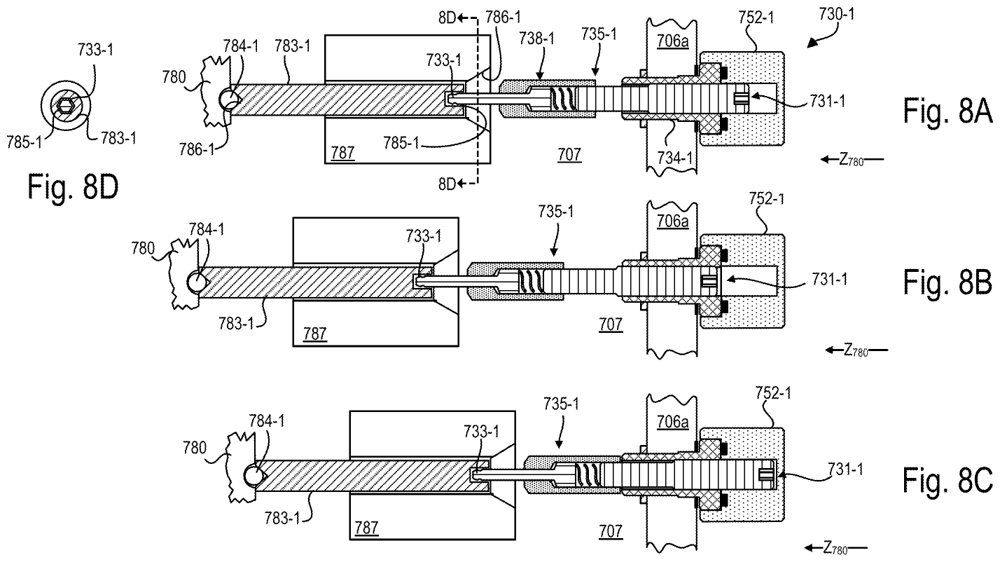

The concave mirror 780 can be in physical communication with three actuation devices 730-1, 730-2, 730-3 at three distinct points 781-1, 781-2, 781-3 on a back surface 782 of the mirror 780. Each actuation device 730-1, 730-2, 730-3 includes a respective driving element 735-1, 735-2, 735-3 extending along a direction Z₇₈₀. The driving element 735-1, 735-2, 735-3 includes a respective adjustment mechanism 731-1, 731-2, 731-3 external to the interior cavity 707 and a respective driver 733-1, 733-2, 733-3 inside the interior cavity 707. The driving element 735-1, 735-2, 735-3 translates relative to the respective bushing 734-1, 734-2, 734-3 fixed within (and hermetically sealed within) the wall 706a along the direction Z₇₈₀. In order to visualize the adjustment mechanism 731-1, 731-2, 731-2, the external cap (such as the cap 252-j) is not shown in FIG. 7. However, each adjustment mechanism 731-1, 731-2, 731-3 can be covered with a respective cap when not being engaged for adjustment, as described above with reference to FIGS. 2A-2E and as shown in FIGS. 8A-8C (where the cap 752-1 is shown covering the adjustment mechanism 731-1).

In some implementations, such as shown in FIG. 7, each driver 733-1, 733-2, 733-3 engages a respective adapter 783-1, 783-2, 783-3 instead of engaging directly with the points 781-1, 781-2, 781-3. At the side of the mirror 780, each adapter 783-1, 783-2, 783-3 includes a respective socket (shown in FIG. 8A) for receiving a sphere 784-1, 784-2, 784-3 positioned at the respective point 781-1, 781-2, 781-3. Additionally, at the other side, each adapter 783-1, 783-2, 783-4 includes a socket (shown in FIGS. 8A-8C) that is shaped to complement the shape of the driver 733-1, 733-2, 733-3. Operation of the actuation device 730-1 is shown below with reference to FIGS. 8A-8C. The operation of the other actuation devices 730-2 and 730-3 is similar to the operation of the actuation device 730-1.

By contacting the mirror 780 at three points 781-1, 781-2, 781-3, the translation imparted at respective drivers 733-1, 733-2, 733-3 and therefore imparted to respective points 781-1, 781-2, 781-3 of the back surface 782 of the mirror 780 enables different kinds of adjustments to the mirror 780. For example, by translating two of the drivers 733-1 and 733-2 and leaving one driver 733-3 still, it is possible to rotate the mirror 780 about the Y₇₈₀ direction or by translating the two drivers 733-2 and 733-3 while leaving one driver 733-1 still, the mirror 780 is rotated about the X₇₈₀ direction. On the other hand, translating all three drivers 733-1, 733-2, 733-3 enables the entire mirror 780 to be translated along the Z₇₈₀ direction. It is alternatively or additionally possible to translate the mirror 780 along the X₇₈₀ direction or the Y₇₈₀ direction or to rotate the mirror 780 about the Z₇₈₀ direction by engaging the mirror 780 at points on other surfaces of the mirror 780.

FIGS. 8A-8C show a side cross-sectional view through the mirror 780, the adapter 783-1, and the respective actuation device 730-1. As shown, the driver 733-1 is engaged within a socket 785-1 of the adapter 783-1 while the sphere 784-1 is nestled between a cavity at the back surface 782 of the mirror 780 and the socket 786-1 of the adapter 783-1. If the tip of the driver 733-1 is a hexagonal shape (in the XY cross section), then the socket 785-1 is a complementary hexagonal socket, as shown in the cross section taken along the XY plane in FIG. 8D.

In FIG. 8A, the “neutral” position is shown. In FIG. 8B, the adjustment mechanism 731-1 has been turned (for example, clockwise when facing the wall 706a from outside the interior cavity 707) relative to the position shown in FIG. 8A. This clockwise rotation causes the driver 733-1 to be translated along the +Z₇₈₀ direction. In FIG. 8C, the adjustment mechanism 731-1 has been turned (for example, counter-clockwise when facing the wall 706a from outside the interior cavity 707) relative to the position shown in FIG. 8A. This counter-clockwise rotation causes the driver 733-1 to be translated along the −Z₇₈₀ direction. Meanwhile, the driver 733-1 remains engages in the socket 785-1 because the driver 733-1 is biased along the +Z₇₈₀ direction by the biasing apparatus 738-1 (which can be designed similarly to the biasing apparatus 238-j discussed above). In one example, the driver 733-1 translates in a range of ±3 millimeters (mm) relative to the neutral position of FIG. 8A, and this translation enables translation of the point at the back surface 782 of the mirror 780 in the range of ±3 mm. The adjustment of the mirror 780 can be done with an accuracy of less than 300 micrometers (μm). As discussed above, the mirror 780 can be rotated, for example, by translating two of the drivers 733-1 and 733-2 and leaving one driver 733-3 still to thereby rotate the mirror 780 about the Y₇₈₀ axis or by translating the two drivers 733-2 and 733-3 while leaving one driver 733-1 still to thereby rotate the mirror about the X₇₈₀ axis. The mirror 780 can be rotated within an adjustment range of ±5 degrees and with a nominal angular accuracy of less than 0.1 degree.

While installing the actuation device 730-1 in the wall 706a, the tip of the driver 733-1 is guided into the socket 785-1 by way of a conical feature 786-1 formed into a mount 787 in which the adapter 783-1 is at least partially fitted. The conical feature 786-1 is designed as a feed-through and enabled the alignment between the tip of the driver 733-1 and the socket 785-1. Additionally, because of the biasing function performed by the biasing apparatus 738-1, the driver 733-1 is in elastic engagement with the adjustment mechanism 731-1. And, the driving element 735-1 remains in physical communication with the mirror 780 during all range of motions of the driving element 735-1 relative to the bushing 734-1, including the positions shown in FIGS. 8A-8C.

While details of the actuation device 730-1 are shown in FIGS. 7 and 8A-8D, the operation of the actuation device 730-1 is similar to the other actuation devices discussed herein. Thus, the actuation devices 530-j of FIG. 5A can operate similarly to the actuation device 730-1. Moreover, even though they are controlling something other than a mirror, the actuation devices 530-4, 530-5 can operate similarly to the actuation device 730-1.

The embodiments can be further described using the following clauses:

1. An optical pulse stretcher apparatus comprising:
a hermetically-sealed container including one or more walls that define an interior cavity that is maintained, in operation, at a controlled environment, at least one wall having one or more windows, each window configured to pass one or more of a pulsed light beam and a stretched pulsed light beam;
an optical stretcher arranged within the interior cavity and configured to receive a pulsed light beam and generate at least one stretched pulsed light beam; and
one or more actuation devices, each actuation device physically communicating with an optical element within the interior cavity and including an adjustment mechanism external to the hermetically-sealed container, wherein the adjustment mechanism enables adjustment of one or more physical properties of the optical element in physical communication with the actuation device without disrupting the controlled environment within the interior cavity.
   2. The optical pulse stretcher apparatus of clause 1, wherein the adjustment mechanism enabling adjustment of one or more physical properties of the optical element comprises the adjustment mechanism enabling one or more of a translation of the optical element along any direction and a rotation of the optical element about any direction.
   3. The optical pulse stretcher apparatus of clause 2, wherein the adjustment mechanism enabling the translation of the optical element along a direction comprises enabling translation of the optical element within an adjustment range of ±3 millimeters (mm) and with a nominal position accuracy of less than 300 micrometers (μm), and the adjustment mechanism enabling the rotation of the optical element about a direction comprises enabling rotation of the optical element within an adjustment range of ±5 degrees and with a nominal angular accuracy of less than 0.1 deg.
   4. The optical pulse stretcher apparatus of clause 1, wherein the optical element that is in physical communication with the actuation device includes a mirror, a concave mirror, a beam splitter, or a prism.
   5. The optical pulse stretcher apparatus of clause 1, wherein the optical element that is in physical communication with the actuation device includes an alignment apparatus comprising a prism and a fluorescent screen arranged in fixed relationship to each other, and the optical pulse stretcher apparatus further comprises a viewport arranged in a wall of the hermetically-sealed container relative to the fluorescent screen such that the fluorescent screen is visible from outside the hermetically-sealed container through the viewport.
   6. The optical pulse stretcher apparatus of clause 5, wherein the actuation device physically communicating with the alignment apparatus is configured to translate the alignment apparatus from a first position at which the prism interacts with one or more of the pulsed light beam and the stretched pulsed light beam and a second position at which the prism does not interact with any pulsed light beam or stretched pulsed light beam.
   7. The optical pulse stretcher apparatus of clause 1, wherein each actuation device comprises a bushing hermetically sealed within a wall of the container and a driving element configured to move relative to the bushing, the driving element physically communicating with the optical element.
   8. The optical pulse stretcher apparatus of clause 7, wherein the bushing is positioned and fixed within a bore of a wall of the container and the driving element includes the adjustment mechanism at a first end and a shaped-tip driver at a second end, the shaped-tip driver sized to interact with a shaped socket physically communicating with the optical element.
   9. The optical pulse stretcher apparatus of clause 8, wherein the shaped socket includes a conical feed-through feature configured to align the shaped-tip driver with the shaped socket.
   10. The optical pulse stretcher apparatus of clause 8, wherein rotation of the adjustment mechanism at the first end translates the shaped-tip driver at the second end, which thereby translates the shaped socket in physical communication with the optical element.
   11. The optical pulse stretcher apparatus of clause 8, wherein the shaped-tip driver is a hex-tip driver and the shaped socket is a hex socket.
   12. The optical pulse stretcher apparatus of clause 8, wherein an interior of the bushing receives the adjustment mechanism and the interface between the bushing and the adjustment mechanism is a threaded interface such that rotation of the adjustment mechanism causes the adjustment mechanism to also translate relative to the bushing and causes the shaped-tip driver to translate and rotate relative to the bushing.
   13. The optical pulse stretcher apparatus of clause 12, wherein the threaded interface includes rounded-tipped threads at the interior of the bushing that mate with rounded-tipped threads at an exterior of the adjustment mechanism.
   14. The optical pulse stretcher apparatus of clause 12, wherein the bushing and the adjustment mechanism are each made of non-leaded metals or non-leaded metal alloys and the interface lacks lubricant.
   15. The optical pulse stretcher apparatus of clause 12, wherein the threaded interface includes threads at the interior of the bushing that mate with threads at the exterior of the adjustment mechanism, the threads having a pitch of 80-100 teeth per inch.
   16. The optical pulse stretcher apparatus of clause 8, wherein the shaped-tip driver is in elastic engagement with the adjustment mechanism.
   17. The optical pulse stretcher apparatus of clause 5, wherein the driving element remains in physical communication with the optical element during all range of motions within the bushing.
   18. The optical pulse stretcher apparatus of clause 5, wherein the adjustment mechanism enables adjustment of one or more physical properties of the optical element in physical communication with the actuation device while passing one or more pulsed light beams and stretched pulsed light beams through the window, and while operating the pulsed light beams and stretched pulsed light beam at repetition rates greater than 500 Hertz (Hz), greater than 1000 Hz, or greater than 3000 Hz.
   19. The optical pulse stretcher apparatus of clause 1, wherein the controlled environment is gas purged and maintained at a pressure greater than atmospheric pressure, or at a pressure that is about 15-22 pounds per square inch (PSI).
   20. The optical pulse stretcher apparatus of clause 1, wherein the optical stretcher includes two or more stacked confocal optical pulse stretchers arranged within the interior cavity,
a first of the stacked confocal optical pulse stretchers comprising a first plurality of mirrors and being configured to receive a portion of the pulsed light beam and generate a first stretched pulsed light beam by reflecting the portion of the pulsed light beam at the first plurality of mirrors; and
a second of the stacked confocal optical pulse stretchers comprising a second plurality of mirrors and being configured to receive a portion of the first stretched pulsed light beam and generate a second stretched pulsed light beam by reflecting the portion of the first stretched pulsed light beam at the second plurality of mirrors.
   21. The optical pulse stretcher apparatus of clause 20, wherein the first plurality of mirrors and the second plurality of mirrors comprise concave mirrors.
   22. The optical pulse stretcher apparatus of clause 1, wherein the optical element that is in physical communication with the actuation device includes an optical element of the optical stretcher.
   23. A deep ultraviolet (DUV) light source comprising:
an optical pulse stretcher apparatus comprising:
a hermetically-sealed container including one or more walls that define an interior cavity that is maintained, in operation, at a controlled environment, at least one wall having one or more windows, each window configured to pass one or more of a pulsed light beam and a stretched pulsed light beam;
an optical stretcher arranged within the interior cavity and configured to receive a pulsed light beam and generate at least one stretched pulsed light beam; and
one or more actuation devices, each actuation device physically communicating with an optical element within the interior cavity and including an adjustment mechanism external to the hermetically-sealed container, wherein the adjustment mechanism enables adjustment of one or more physical properties of the optical element in physical communication with the actuation device without disrupting the controlled environment within the interior cavity.

Other implementations are within the scope of the following claims.

1. An optical pulse stretcher apparatus comprising:
a hermetically-sealed container including one or more walls that define an interior cavity that is maintained, in operation, at a controlled environment, at least one wall having one or more windows, each window configured to pass one or more of a pulsed light beam and a stretched pulsed light beam;
an optical stretcher arranged within the interior cavity and configured to receive a pulsed light beam and generate at least one stretched pulsed light beam; and
one or more actuation devices, each actuation device physically communicating with an optical element within the interior cavity and including an adjustment mechanism external to the hermetically-sealed container, wherein the adjustment mechanism enables adjustment of one or more physical properties of the optical element in physical communication with the actuation device without disrupting the controlled environment within the interior cavity.

2. The optical pulse stretcher apparatus of claim 1, wherein the adjustment mechanism enabling adjustment of one or more physical properties of the optical element comprises the adjustment mechanism enabling one or more of a translation of the optical element along any direction and a rotation of the optical element about any direction.

3. The optical pulse stretcher apparatus of claim 2, wherein the adjustment mechanism enabling the translation of the optical element along a direction comprises enabling translation of the optical element within an adjustment range of ±3 millimeters (mm) and with a nominal position accuracy of less than 300 micrometers (μm), and the adjustment mechanism enabling the rotation of the optical element about a direction comprises enabling rotation of the optical element within an adjustment range of ±5 degrees and with a nominal angular accuracy of less than 0.1 deg.

4. The optical pulse stretcher apparatus of claim 1, wherein the optical element that is in physical communication with the actuation device includes a mirror, a concave mirror, a beam splitter, or a prism.

5. The optical pulse stretcher apparatus of claim 1, wherein the optical element that is in physical communication with the actuation device includes an alignment apparatus comprising a prism and a fluorescent screen arranged in fixed relationship to each other, and the optical pulse stretcher apparatus further comprises a viewport arranged in a wall of the hermetically-sealed container relative to the fluorescent screen such that the fluorescent screen is visible from outside the hermetically-sealed container through the viewport.

6. The optical pulse stretcher apparatus of claim 5, wherein the actuation device physically communicating with the alignment apparatus is configured to translate the alignment apparatus from a first position at which the prism interacts with one or more of the pulsed light beam and the stretched pulsed light beam and a second position at which the prism does not interact with any pulsed light beam or stretched pulsed light beam.

7. The optical pulse stretcher apparatus of claim 1, wherein each actuation device comprises a bushing hermetically sealed within a wall of the container and a driving element configured to move relative to the bushing, the driving element physically communicating with the optical element.

8. The optical pulse stretcher apparatus of claim 7, wherein the bushing is positioned and fixed within a bore of a wall of the container and the driving element includes the adjustment mechanism at a first end and a shaped-tip driver at a second end, the shaped-tip driver sized to interact with a shaped socket physically communicating with the optical element.

9. The optical pulse stretcher apparatus of claim 8, wherein the shaped socket includes a conical feed-through feature configured to align the shaped-tip driver with the shaped socket.

10. The optical pulse stretcher apparatus of claim 8, wherein rotation of the adjustment mechanism at the first end translates the shaped-tip driver at the second end, which thereby translates the shaped socket in physical communication with the optical element.

11. The optical pulse stretcher apparatus of claim 8, wherein the shaped-tip driver is a hex-tip driver and the shaped socket is a hex socket.

12. The optical pulse stretcher apparatus of claim 8, wherein an interior of the bushing receives the adjustment mechanism and the interface between the bushing and the adjustment mechanism is a threaded interface such that rotation of the adjustment mechanism causes the adjustment mechanism to also translate relative to the bushing and causes the shaped-tip driver to translate and rotate relative to the bushing.

13. The optical pulse stretcher apparatus of claim 12, wherein the threaded interface includes rounded-tipped threads at the interior of the bushing that mate with rounded-tipped threads at an exterior of the adjustment mechanism.

14. The optical pulse stretcher apparatus of claim 12, wherein the bushing and the adjustment mechanism are each made of non-leaded metals or non-leaded metal alloys and the interface lacks lubricant.

15. The optical pulse stretcher apparatus of claim 12, wherein the threaded interface includes threads at the interior of the bushing that mate with threads at the exterior of the adjustment mechanism, the threads having a pitch of 80-100 teeth per inch.

16. The optical pulse stretcher apparatus of claim 8, wherein the shaped-tip driver is in elastic engagement with the adjustment mechanism.

17. The optical pulse stretcher apparatus of claim 5, wherein the driving element remains in physical communication with the optical element during all range of motions within the bushing.

18. The optical pulse stretcher apparatus of claim 5, wherein the adjustment mechanism enables adjustment of one or more physical properties of the optical element in physical communication with the actuation device while passing one or more pulsed light beams and stretched pulsed light beams through the window, and while operating the pulsed light beams and stretched pulsed light beam at repetition rates greater than 500 Hertz (Hz), greater than 1000 Hz, or greater than 3000 Hz.

19. The optical pulse stretcher apparatus of claim 1, wherein the controlled environment is gas purged and maintained at a pressure greater than atmospheric pressure, or at a pressure that is about 15-22 pounds per square inch (PSI).

20. The optical pulse stretcher apparatus of claim 1, wherein the optical stretcher includes two or more stacked confocal optical pulse stretchers arranged within the interior cavity,
a first of the stacked confocal optical pulse stretchers comprising a first plurality of mirrors and being configured to receive a portion of the pulsed light beam and generate a first stretched pulsed light beam by reflecting the portion of the pulsed light beam at the first plurality of mirrors; and
a second of the stacked confocal optical pulse stretchers comprising a second plurality of mirrors and being configured to receive a portion of the first stretched pulsed light beam and generate a second stretched pulsed light beam by reflecting the portion of the first stretched pulsed light beam at the second plurality of mirrors.

21. The optical pulse stretcher apparatus of claim 20, wherein the first plurality of mirrors and the second plurality of mirrors comprise concave mirrors.

22. The optical pulse stretcher apparatus of claim 1, wherein the optical element that is in physical communication with the actuation device includes an optical element of the optical stretcher.

23. A deep ultraviolet (DUV) light source comprising:
an optical pulse stretcher apparatus comprising:
a hermetically-sealed container including one or more walls that define an interior cavity that is maintained, in operation, at a controlled environment, at least one wall having one or more windows, each window configured to pass one or more of a pulsed light beam and a stretched pulsed light beam;
an optical stretcher arranged within the interior cavity and configured to receive a pulsed light beam and generate at least one stretched pulsed light beam; and
one or more actuation devices, each actuation device physically communicating with an optical element within the interior cavity and including an adjustment mechanism external to the hermetically-sealed container, wherein the adjustment mechanism enables adjustment of one or more physical properties of the optical element in physical communication with the actuation device without disrupting the controlled environment within the interior cavity.
